(19) United States
(12) Patent Application Publication
(10) Pub. No.: US 2024/0128257 A1
(43) Pub. Date: Apr. 18, 2024

(54) INTEGRATED CIRCUIT INCLUDING STANDARD CELLS AND METHOD OF DESIGNING THE SAME

(71) Applicant: Samsung Electronics Co., Ltd., Suwon-si (KR)

(72) Inventors: Dalhee LEE, Suwon-si (KR); Byounggon KANG, Suwon-si (KR); Wookyu KIM, Suwon-si (KR); Changbeom KIM, Suwon-si (KR); Minjung PARK, Suwon-si (KR); Taejun YOO, Suwon-si (KR)

(73) Assignee: Samsung Electronics Co., Ltd., Suwon-si (KR)

(21) Appl. No.: 18/481,443

(22) Filed: Oct. 5, 2023

(30) Foreign Application Priority Data
Oct. 14, 2022 (KR) 10-2022-0132466
Jan. 30, 2023 (KR) 10-2023-0011946

(51) Int. Cl. H01L 27/02; H03K 19/20

(52) U.S. Cl. CPC H01L 27/0207; H03K 19/20

(57) ABSTRACT

An integrated circuit includes a plurality of cells in a series of rows, wherein a first cell of the plurality of cells includes a plurality of logic circuits, each logic circuit of the plurality of logic circuits configured to independently generate an output bit signal according to input bit signals, a first input pin group including at least one input pin commonly connected to the plurality of logic circuits, a second input pin group including at least one input pin commonly connected to two or more logic circuits among the plurality of logic circuits, and a third input pin group including at least one input pin respectively connected exclusively to at least one of the plurality of logic circuits.

### CROSS-REFERENCE TO RELATED APPLICATIONS

This application is based on and claims priority under 35 U.S.C. § 119 to Korean Patent Application Nos. 10-2022-0132466, filed on Oct. 14, 2022, and 10-2023-0011946, filed on Jan. 30, 2023, in the Korean Intellectual Property Office, the disclosures of which are incorporated by reference herein in their entirety.

### BACKGROUND

Although the development of semiconductor processes may reduce the size of elements included in integrated circuits, routing congestion may occur in order to interconnect the elements of reduced size. Accordingly, it may be advantageous to eliminate routing congestion for a higher degree of integration of integrated circuits.

### SUMMARY

The inventive concepts relate to an integrated circuit, and more particularly, to an integrated circuit including a standard cell and a method of designing the same.

Example embodiments of the inventive concepts provide an integrated circuit including a standard cell, which solves routing congestion, and a method of designing the same.

According to some example embodiments of the inventive concepts, an integrated circuit includes cells in a series of rows, wherein a first cell of the plurality of cells includes a plurality of logic circuits, each logic circuit of the plurality of logic circuits configured to independently generate an output bit signal according to input bit signals, a first input pin group including at least one input pin commonly connected to the plurality of logic circuits, a second input pin group including at least one input pin commonly connected to two or more logic circuits among the plurality of logic circuits, and a third input pin group including at least one input pin respectively connected exclusively to at least one of the plurality of logic circuits.

According to some example embodiments of the inventive concepts, an integrated circuit includes a plurality of cells in a series of rows, wherein a first cell of the plurality of cells includes a plurality of logic circuits, each logic circuit of the plurality of logic circuits corresponding to an identical logic and configured to independently generate an output bit signal according to input bit signals, a first input pin group including at least one input pin commonly connected to the plurality of logic circuits, and a second input pin group including a plurality of input pins respectively connected exclusively to the plurality of logic circuits.

According to some example embodiments of the inventive concepts, an integrated circuit includes a plurality of cells in a series of rows, wherein a first cell of the plurality of cells includes a first input pin group, a second input pin group, a first logic circuit configured to generate an internal bit signal based on first input bit signals received via the first input pin group, and a second logic circuit configured to generate an output bit signal based on the internal bit signal received from the first logic circuit and on second input bit signals received via the second input pin group, and the first logic circuit may correspond to a logic including two or more cascaded logic gates.

### BRIEF DESCRIPTION OF THE DRAWINGS

Some example embodiments will be more clearly understood from the following detailed description taken in conjunction with the accompanying drawings in which:

FIG. 1 is a block diagram showing a cell according to some example embodiments;

FIG. 2 is a diagram showing a layout of an integrated circuit according to some example embodiments;

FIGS. 3A and 3B are diagrams showing an example of a standard cell according to some example embodiments;

FIGS. 4A to 4D are diagrams showing examples of an element according to some example embodiments;

FIG. 5 is a block diagram showing a cell according to some example embodiments;

FIGS. 6A to 6D are diagrams showing examples of a cell according to some example embodiments;

FIG. 7 is a block diagram showing a cell according to some example embodiments;

FIG. 8 is a diagram showing a cell according to some example embodiments;

FIG. 9 is a block diagram showing a cell according to some example embodiments;

FIGS. 10A and 10B are diagrams showing examples of a cell according to some example embodiments;

FIG. 11 is a flowchart showing a method of manufacturing an integrated circuit, according to some example embodiments;

FIG. 12 is a flowchart showing a method of designing an integrated circuit, according to some example embodiments;

FIG. 13 is a block diagram showing a system-on-chip according to some example embodiments; and

FIG. 14 is a block diagram showing a computing system including a memory storing a program, according to some example embodiments.

### DETAILED DESCRIPTION

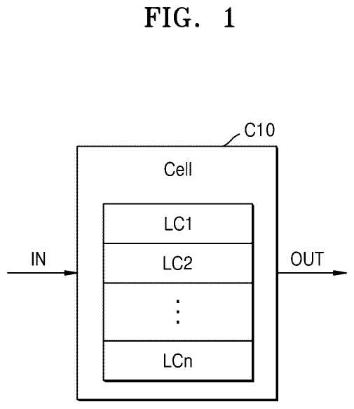

FIG. 1 is a block diagram showing a cell C10 according to some example embodiments. As shown in FIG. 1, the cell C10 may receive an input signal IN and generate an output signal OUT. The cell C10 may include an input pin for receiving the input signal IN, and may include an output pin for outputting the output signal OUT. In some example embodiments, the input signal IN and/or the output signal OUT may be a multi-bit signal, and the cell C10 may include a plurality of input pins and a plurality of output pins.

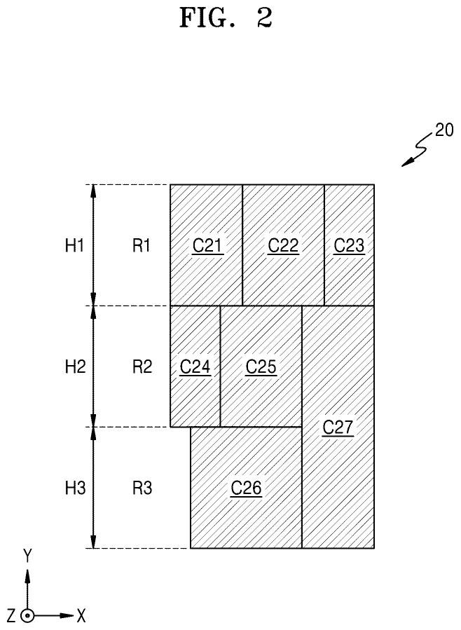

The cell C10 may be included in an integrated circuit as a standard cell. A standard cell is a unit of a layout included in an integrated circuit, and may be designed to perform a predefined (or alternatively given) function. The standard cell may comply with a predefined (or alternatively given) rule, and may have, for example, a predefined (or alternatively given) height as described below with reference to FIG. 2. Herein, a standard cell may be simply referred to as a cell.

Referring to FIG. 1, the cell C10 may include first to n^{th} logic circuits LC1 to LCn. Each, or one or more, of the first to n^{th} logic circuits LC1 to LCn may independently generate an output bit signal based on input bit signals. In some example embodiments, the first to n th logic circuits LC1 to LCn may include a logic circuit that receives at least one bit of the input signal IN and generates one bit of the output signal OUT. In some example embodiments, the first to n^{th} logic circuits LC1 to LCn may include a logic circuit that receives at least one bit of the input signal IN and generates an internal bit signal. In some example embodiments, the first to n^{th} logic circuits LC1 to LCn may include a logic circuit that receives an internal bit signal generated by another logic circuit and generates one bit of the output signal OUT.

Each, or one or more, of the first to n^{th} logic circuits LC1 to LCn may be connected to another logic circuit in the cell C10. In some example embodiments, the first logic circuit LC1 and the second logic circuit LC2 may commonly receive at least one bit of the input signal IN, and accordingly, may be commonly connected to at least one input pin of the cell C10. In some example embodiments, inputs of the n^{th} logic circuit LCn may be respectively connected to an output of the first logic circuit LC1 and an input of the second logic circuit LC2. Herein, a standard cell including a plurality of logic circuits, such as the cell C10, may be referred to as a complex cell or a complex logic cell.

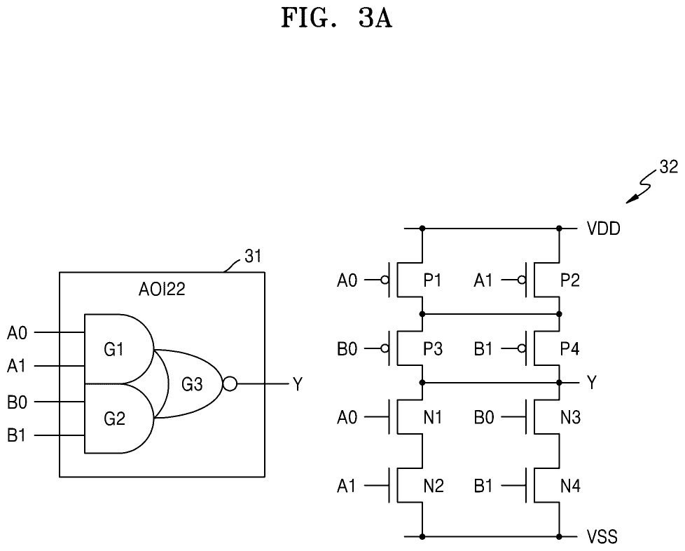

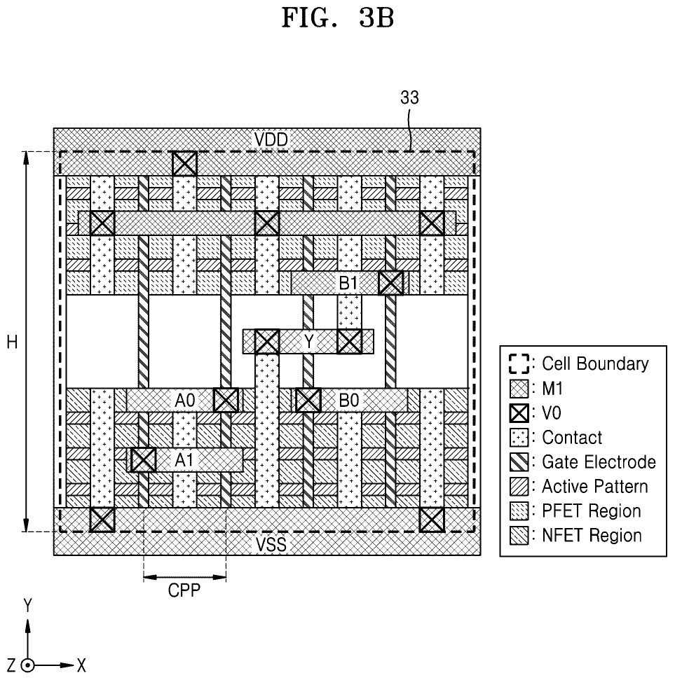

As described below with reference to FIGS. 3A and 3B, a standard cell corresponding to one logic circuit may be provided. When an integrated circuit includes first to n^{th} cells respectively corresponding to the first to n^{th} logic circuits LC1 to LCn, the integrated circuit may include patterns, which are for interconnecting the first to n^{th} cells, outside the first to n th cells. However, as shown in FIG. 1, when an integrated circuit include the cell C10 including the first to n^{th} logic circuits LC1 to LCn, patterns for interconnecting the first to n^{th} logic circuits LC1 to LCn may be included in the cell C10. Accordingly, in the integrated circuit, routing resources may be increased and routing congestion may be reduced or eliminated. In addition, parasitic components of wiring lines may be reduced due to the increased routing resources, and performance of the integrated circuit may be improved. In addition, the integrated circuit may have a higher degree of integration and/or a smaller area.

FIG. 2 is a diagram showing a layout of an integrated circuit according to some example embodiments. For example, FIG. 2 is a plan view showing a layout of an integrated circuit 20 in a −Z-axis direction. Herein, an X-axis direction and a Y-axis direction may each be referred to as a horizontal direction, and a Z-axis direction may be referred to as a vertical direction. A plane formed by an X axis and a Y axis may be referred to as a horizontal plane, a component relatively arranged in a +Z direction than another component may be considered to be above the other component, and a component relatively arranged in a −Z direction than another component may be considered to be under the other component. In addition, the area of a component may refer to a size occupied by the component on a plane parallel to a horizontal plane, and the width of a component may refer to a length in a direction perpendicular to a direction in which the component extends. A surface exposed in the +Z direction may be referred to as a top surface, a surface exposed in the +Z direction may be referred to as a bottom surface, and a surface exposed in a ±X direction or ±Y direction may be referred to as a side surface. For convenience of illustration, only some layers may be shown in the drawings, and for understanding, although a via connecting an upper pattern and a lower pattern together is located under the upper pattern, the via may be illustrated in the upper pattern. In addition, a pattern including a conductive material, such as a pattern of a wiring layer, may be referred to as a conductive pattern or may simply be referred to as a pattern.

The integrated circuit 20 may include standard cells arranged in a series of rows extending in an X-axis direction. For example, as shown in FIG. 2, first to third rows R1 to R3 may extend in the X-axis direction and may have first to third heights H1 to H3 in a Y-axis direction, respectively. The first to third heights H1 to H3 may be identical to or different from each other. As shown in FIG. 2, first to third cells C21 to C23 having the first height H1 may be arranged in the first row R1, a fourth cell C24 and/or a fifth cell C25, each having the second height H2, may be arranged in the second row R2, and/or a sixth cell C26 having the third height H3 may be arranged in the third row R3. In addition, a seventh cell C27 having a height obtained by adding the second height H2 and the third height H3 may be arranged in the second row R2 and the third row R3, which are adjacent to each other. Standard cells arranged in one row, such as the first to sixth cells C21 to C26, may be referred to as single-height cells, and standard cells arranged in two or more consecutive rows, such as the seventh cell C27, may be referred to as multi-height cells. As described above with reference to FIG. 1, the integrated circuit 20 may include a complex logic cell, and at least one of the first to seventh cells C21 to C27 may include a plurality of logic circuits.

FIGS. 3A and 3B are diagrams showing an example of a standard cell according to some example embodiments. For example, FIG. 3A shows a logic 31 of an AOI22 cell and an equivalent circuit 32, and FIG. 3B shows a layout 33 of the AOI22 cell.

In some example embodiments, a standard cell corresponding to one logic circuit may be provided. For example, like the logic 31 of FIG. 3A, the AOI22 cell may correspond to a logic (or function) including a first AND gate G1, a second AND gate G2, and/or a NOR gate G3. Input bit signals A0 and A1 may correspond to inputs of the first AND gate G1, input bit signals B0 and B1 may correspond to inputs of the second AND gate G2, and an output bit signal Y may correspond to an output of the NOR gate G3.

The AOI22 cell may be implemented as a plurality of transistors. As shown in FIG. 3A, the equivalent circuit 32 may operate based on power provided by a positive supply voltage VDD and a negative supply voltage VSS. The equivalent circuit 32 may include first to fourth p-channel field effect transistors (PFETs) P1 to P4 and first to fourth n-channel field effect transistors (NFETs) N1 to N4.

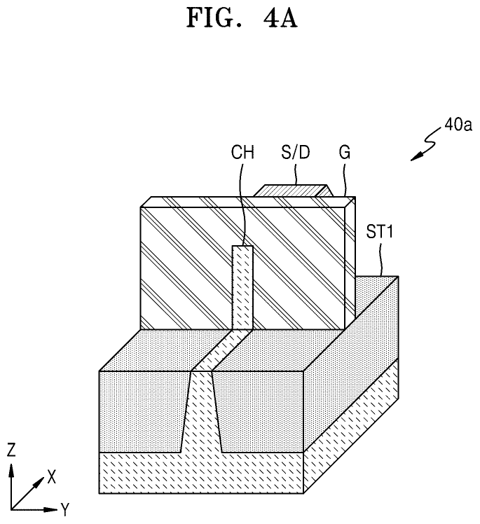

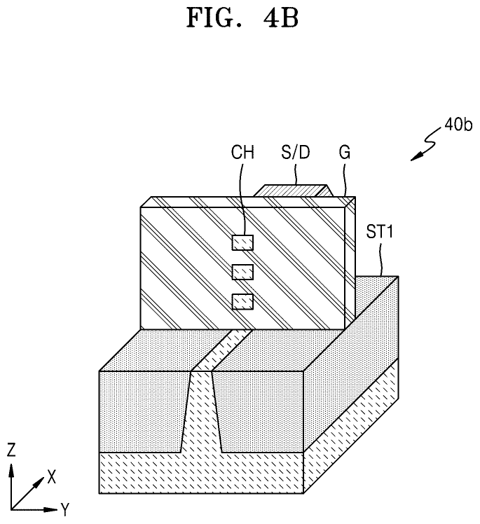

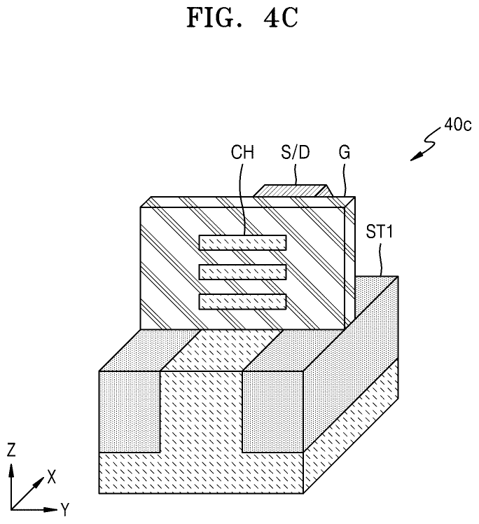

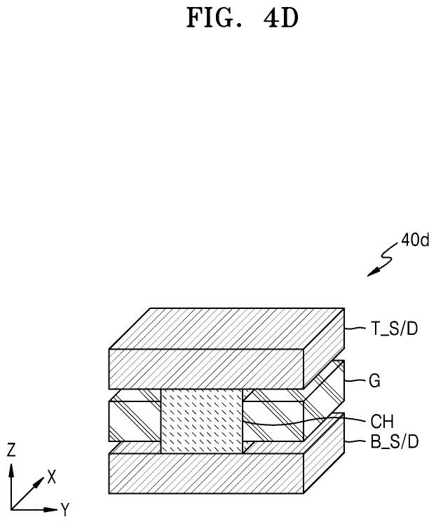

Referring to FIG. 3B, the layout 33 may include a PFET region and an NFET region extending parallel to each other in an X-axis direction. Active patterns may extend parallel to each other in the X-axis direction in each of the PFET region and the NFET region. Although FIG. 3B illustrates an example in which three active patterns extend in each of the PFET region and the NFET region, a standard cell may include elements of various structures, and examples of devices are described below with reference to FIGS. 4A to 4D. Gate electrodes may extend parallel to each other in a Y-axis direction, and a pitch between gate electrodes adjacent to each other may be referred to as a contacted poly pitch (CPP). For convenience of illustration, although not shown in FIG. 3B, a source and a drain of a transistor may be formed at both sides of a gate electrode, respectively. A contact may be disposed on a gate electrode, a source, and a drain, and a via of a first via layer V0 may be disposed on the contact. The via of the first via layer V0 may be connected to a pattern of a first wiring layer M1, and patterns of the first wiring layer M1 may extend in the X-axis direction.

The layout 33 may include input pins corresponding to four input bit signals A0, A1, B0, and/or B1 and/or an output pin corresponding to the output bit signal Y. For example, as shown in FIG. 3B, the layout 33 may include patterns of the first wiring layer M1, respectively corresponding to the four input bit signals A0, A1, B0, and/or B1 and extending in the X-axis direction. In addition, the layout 33 may include a pattern of the first wiring layer M1, corresponding to the output bit signal Y and extending in the X-axis direction.

Like the AOI22 cell, a standard cell having a plurality of input pins relative to its area may cause routing congestion. For example, patterns of a second wiring layer (for example, M2) above the first wiring layer M1 may be used to route a plurality of input pins, that is, patterns of the first wiring layer M1, and accordingly, routing resources of the second wiring layer may be reduced. However, as described above with reference to FIG. 1, when a complex cell including the AOI22 cell and another cell connected to the AOI22 cell is included in an integrated circuit, the AOI22 cell and the other cell may be connected to each other via a pattern of the first wiring layer M1 within the complex cell, and accordingly, routing resources of the second wiring layer may increase.

FIGS. 4A to 4D are diagrams showing examples of an element according to some example embodiments. For example, FIG. 4A shows a FinFET 40a, FIG. 4B shows a gate-all-around field effect transistor (GAAFET) 40b, FIG. 4C shows a multi-bridge channel field effect transistor (MBCFET) 40c, and FIG. 4D shows a vertical field effect transistor (VFET) 40d. For convenience of illustration, FIGS. 4A to 4C illustrate a state in which one of four source/drain regions is removed, and FIG. 4D shows a cross-section of the VFET 40d cut with a plane parallel to a plane formed by a Y axis and a Z axis and passing through a channel CH of the VFET 40d.

Referring to FIG. 4A, the FinFET 40a may include a channel CH formed by a fin-shaped active pattern extending between shallow trench isolations (STIs) in an X-axis direction and a gate G extending in a Y-axis direction. A source/drain regions S/D may be formed at both sides of the gate G, and accordingly, the source and the drain may be apart from each other in the X-axis direction. An insulating film may be formed between the channel CH and the gate G. In some example embodiments, the FinFET 40a may be formed by a plurality of active patterns apart from each other in the Y-axis direction and the gate G.

Referring to FIG. 4B, the GAAFET 40b may include a channel CH formed by active patterns, that is, nanowires, apart from each other in a Z-axis direction and extending in an X-axis direction, and the gate G extending in a Y-axis direction. The source/drain regions S/D may be formed at both sides of the gate G, and accordingly, the source and the drain may be apart from each other in the X-axis direction. An insulating film may be formed between the channel CH and the gate G. The number of nanowires included in the GAAFET 40b is not limited to those shown in FIG. 4B.

Referring to FIG. 4C, the MBCFET 40c may include a channel CH formed by active patterns, that is, nanosheets, apart from each other in a Z-axis direction and extending in an X-axis direction, and the gate G extending in a Y-axis direction. The source/drain regions S/D may be formed at both sides of the gate G, and accordingly, the source and the drain may be apart from each other in the X-axis direction. An insulating film may be formed between the channel CH and the gate G. The number of nanosheets included in the MBCFET 40c is not limited to those shown in FIG. 4C.

Referring to FIG. 4D, the VFET 40d may include a top source/drain region T_S/D and a bottom source/drain region B_S/D, apart from each other in a Z-axis direction, with the channel CH therebetween. The VFET 40d may include the gate G surrounding the perimeter of the channel CH, the gate G being between the top source/drain region T_S/D and the bottom source/drain region B_S/D. An insulating film may be formed between the channel CH and the gate G.

Hereinafter, an integrated circuit including the FinFET 40a or the MBCFET 40c is mainly described, but elements included in the integrated circuit are not limited to examples of FIGS. 4A to 4D. For example, the integrated circuit may include a ForkFET having a structure in which nanosheets for a P-type transistor and nanosheets for an N-type transistor are separated by a dielectric wall to bring the N-type transistor and the P-type transistor closer together. In addition, the integrated circuit may also include a bipolar junction transistor as well as a FET, such as a complementary field effect transistor (CFET), a negative capacitance field effect transistor (NCFET), or a carbon nanotube (CNT) FET.

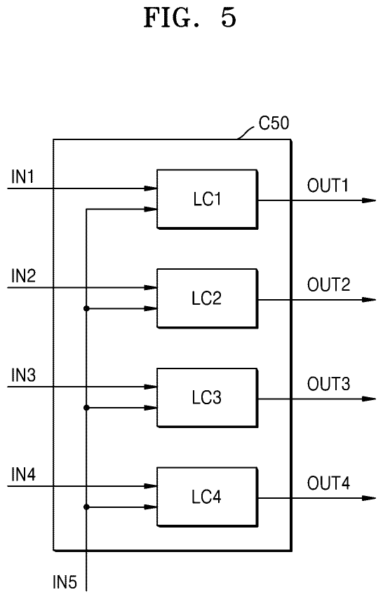

FIG. 5 is a block diagram showing a cell C50 according to some example embodiments. Referring to FIG. 5, the cell C50 may receive first to fifth input signals IN1 to IN5, and may generate first to fourth output signals OUT1 to OUT4. Each, or one or more, of the first to fifth input signals IN1 to IN5 and/or the first to fourth output signals OUT1 to OUT4 may be a single-bit signal or a multi-bit signal. FIG. 5 illustrates the cell C50 including four logic circuits, but a cell may include less than four logic cells or more than four logic cells.

Referring to FIG. 5, the cell C50 may include the first to fourth logic circuits LC1 to LC4. The first logic circuit LC1 may generate the first output signal OUT1 from the first input signal IN1 and the fifth input signal IN5, the second logic circuit LC2 may generate the second output signal OUT2 from the second input signal IN2 and the fifth input signal IN5, the third logic circuit LC3 may generate the third output signal OUT3 from the third input signal IN3 and the fifth input signal IN5, and/or the fourth logic circuit LC4 may generate the fourth output signal OUT4 from the fourth input signal IN4 and the fifth input signal IN5.

The cell C50 may include a first input pin group including at least one input pin commonly connected to the first to fourth logic circuits LC1 to LC4, and/or a second input pin group including a plurality of input pins respectively connected exclusively to the first to fourth logic circuits LC1 to LC4. For example, the first input pin group may include an input pin that receives the fifth input signal IN5, and the second input pin group may include input pins that respectively receive the first to fourth input signals IN1 to IN4. The first to fourth logic circuits LC1 to LC4 may be commonly connected to an input pin included in the first input pin group, and may be respectively connected exclusively to input pins included in the second input pin group. In some example embodiments, the first to fourth logic circuits LC1 to LC4 may correspond to an identical logic. For example, the first to fourth logic circuits LC1 to LC4 may correspond to an AND-OR-Inverter (AOI) logic, an AND-OR (AO) logic, an OR-AND-Inverter (OAI) logic, and/or an OR-AND (OA) logic.

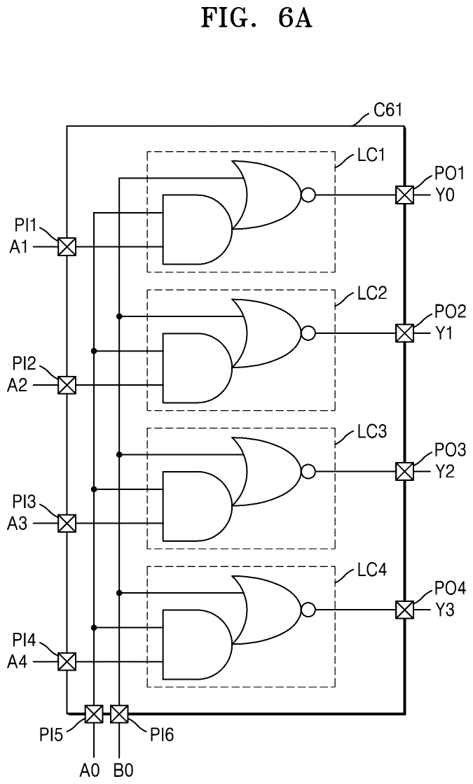

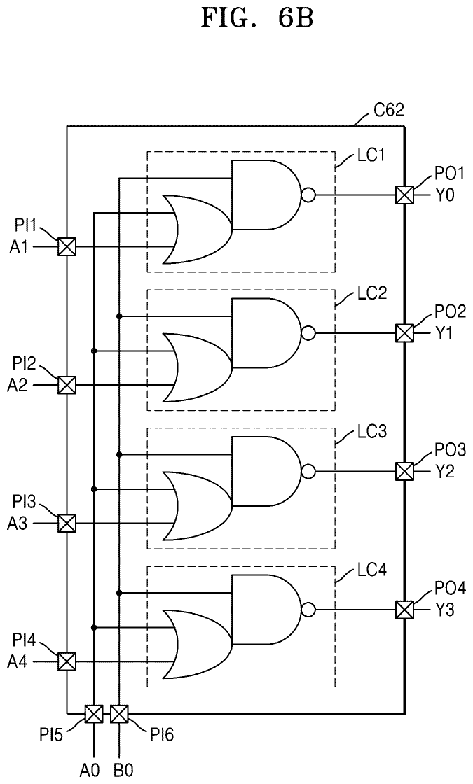

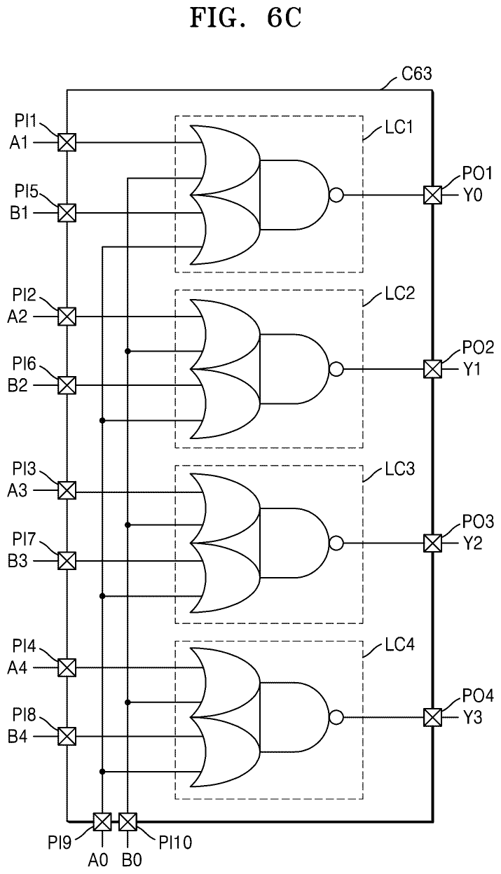

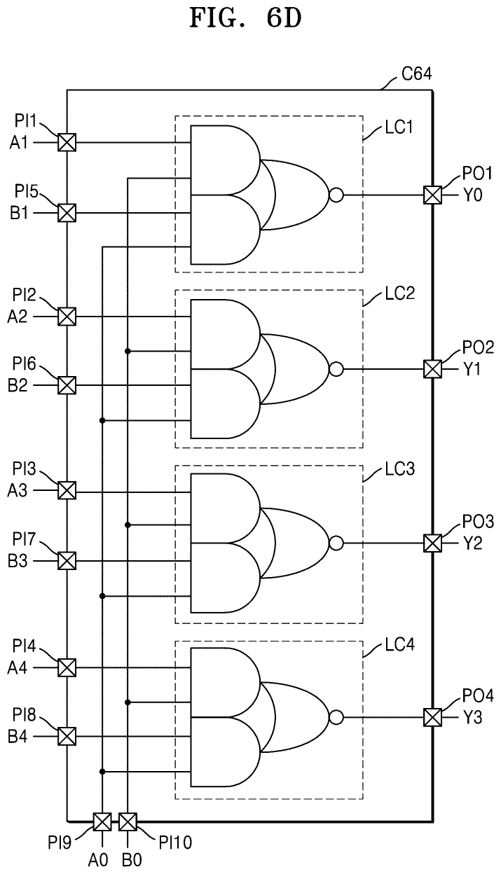

FIGS. 6A to 6D are diagrams showing examples of a cell according to some example embodiments. For example, FIGS. 6A to 6D show examples of the cell C50 of FIG. 5. As described above with reference to FIG. 5, each, or one or more, of cells C61 to C64 of FIGS. 6A to 6D may include a plurality of logic circuits, and may include a first input pin group including at least one input pin commonly connected to the plurality of logic circuits, and/or a second input pin group including a plurality of input pins respectively connected exclusively to the plurality of logic circuits.

Referring to FIG. 6A, the cell C61 may include the first to fourth logic circuits LC1 to LC4, and each of the first to fourth logic circuits LC1 to LC4 may correspond to a logic including a AND gate and a NOR gate which are cascaded. Herein, as shown in FIG. 6A, a logic including an AND gate and a NOR gate may be referred to as an AOI21 logic. The first to fourth logic circuits LC1 to LC4 may commonly receive the input bit signals A0 and/or B0, and may respectively receive exclusively input bit signals A1 to A4. To this end, the first to fourth logic circuits LC1 to LC4 may be commonly connected to fifth and/or sixth input pins PI5 and/or PI6 that receive the input bit signals A0 and/or B0, and may respectively connected exclusively to first to fourth input pins PI1 to PI4 that respectively receive the input bit signals A1 to A4. In other words, the fifth and/or sixth input pins PI5 and/or PI6 may be included in the first input pin group, and the first to fourth input pins PI1 to PI4 may be included in the second input pin group. The first to fourth logic circuits LC1 to LC4 may respectively output output bit signals Y0 to Y3 via first to fourth output pins PO1 to PO4.

Referring to FIG. 6B, the cell C62 may include the first to fourth logic circuits LC1 to LC4, and each of the first to fourth logic circuits LC1 to LC4 may correspond to a logic including a OR gate and a NAND gate which are cascaded. Herein, as shown in FIG. 6B, a logic including an OR gate and a NAND gate may be referred to as an OAI21 logic. The first to fourth logic circuits LC1 to LC4 may commonly receive the input bit signals A0 and/or B0, and may respectively receive exclusively the input bit signals A1 to A4. To this end, the first to fourth logic circuits LC1 to LC4 may be commonly connected to the fifth and/or sixth input pins PI5 and/or PI6 that receive the input bit signals A0 and/or B0, and may respectively connected exclusively to the first to fourth input pins PI1 to PI4 that respectively receive the input bit signals A1 to A4. In other words, the fifth and/or sixth input pins PI5 and/or PI6 may be included in the first input pin group, and the first to fourth input pins PI1 to PI4 may be included in the second input pin group. The first to fourth logic circuits LC1 to LC4 may respectively output the output bit signals Y0 to Y3 via the first to fourth output pins PO1 to PO4.

Referring to FIG. 6C, the cell C63 may include the first to fourth logic circuits LC1 to LC4, and each of the first to fourth logic circuits LC1 to LC4 may correspond to an OAI22 logic. The first to fourth logic circuits LC1 to LC4 may commonly receive the input bit signals A0 and/or B0, may respectively receive exclusively the input bit signals A1 to A4, and may respectively receive exclusively input bit signals B1 to B4. To this end, the first to fourth logic circuits LC1 to LC4 may be commonly connected to ninth and/or tenth input pins PI9 and/or PI10 that receive the input bit signals A0 and/or B0, may be respectively connected exclusively to the first to fourth input pins PI1 to PI4 that respectively receive the input bit signals A1 to A4, and may be respectively connected exclusively to fifth to eighth input pins PI5 to PI8 that respectively receive the input bit signals B1 to B4. In other words, the ninth and/or tenth input pins PI9 and/or PI10 may be included in the first input pin group, and the first to eighth input pins PI1 to PI8 may be included in the second input pin group. The first to fourth logic circuits LC1 to LC4 may respectively output the output bit signals Y0 to Y3 via the first to fourth output pins PO1 to PO4.

Referring to FIG. 6D, the cell C64 may include the first to fourth logic circuits LC1 to LC4, and each of the first to fourth logic circuits LC1 to LC4 may correspond to an AOI22 logic. The first to fourth logic circuits LC1 to LC4 may commonly receive the input bit signals A0 and/or B0, may respectively receive exclusively the input bit signals A1 to A4, and may respectively receive exclusively the input bit signals B1 to B4. To this end, the first to fourth logic circuits LC1 to LC4 may be commonly connected to the ninth and/or tenth input pins PI9 and/or PI10 that receive the input bit signals A0 and/or B0, may be respectively connected exclusively to the first to fourth input pins PI1 to PI4 that respectively receive the input bit signals A1 to A4, and may be respectively connected exclusively to the fifth to eighth input pins PI5 to PI8 that respectively receive the input bit signals B1 to B4. In other words, the ninth and/or tenth input pins PI9 and/or PI10 may be included in the first input pin group, and the first to eighth input pins PI1 to PI8 may be included in the second input pin group. The first to fourth logic circuits LC1 to LC4 may respectively output the output bit signals Y0 to Y3 via the first to fourth output pins PO1 to PO4.

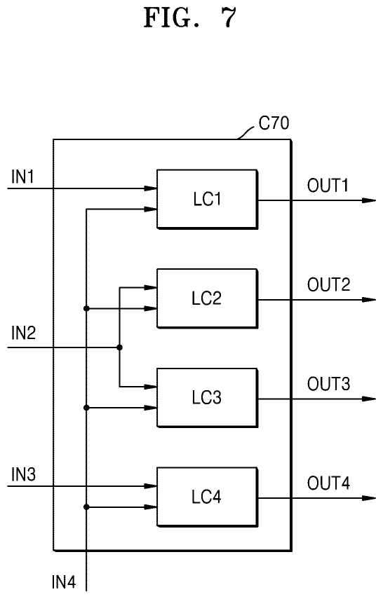

FIG. 7 is a block diagram showing a cell C70 according to some example embodiments. Referring to FIG. 7, the cell C70 may receive the first to fourth input signals IN1 to IN4, and may generate the first to fourth output signals OUT1 to OUT4. Each, or one or more, of the first to fourth input signals IN1 to IN4 and/or the first to fourth output signals OUT1 to OUT4 may be a single-bit signal or a multi-bit signal. FIG. 7 illustrates the cell C70 including four logic circuits, but a cell may include less than four logic cells or more than four logic cells.

Referring to FIG. 7, the cell C70 may include the first to fourth logic circuits LC1 to LC4. The first logic circuit LC1 may generate the first output signal OUT1 from the first input signal IN1 and the fourth input signal IN4, the second logic circuit LC2 may generate the second output signal OUT2 from the second input signal IN2 and the fourth input signal IN4, the third logic circuit LC3 may generate the third output signal OUT3 from the second input signal IN2 and the fourth input signal IN4, and the fourth logic circuit LC4 may generate the fourth output signal OUT4 from the third input signal IN3 and the fourth input signal IN4.

The cell C70 may include a first input pin group including at least one input pin commonly connected to the first to fourth logic circuits LC1 to LC4, a second input pin group including at least one input pin connected to two or more logic circuits among the first to fourth logic circuits LC1 to LC4, and/or a third input pin group including at least one input pin respectively connected exclusively to at least one of the first to fourth logic circuits LC1 to LC4. For example, the first input pin group may include an input pin that receives the fourth input signal IN4, the second input pin group may include an input pin that receives the second input signal IN2, and the third input pin group may include input pins that respectively receive the first input signal IN1 and the third input signal IN3. The first to fourth logic circuits LC1 to LC4 may be commonly connected to an input pin included in the first input pin group. Two or more logic circuits among the first to fourth logic circuits LC1 to LC4, that is, the second logic circuit LC2 and the third logic circuit LC3, may be commonly connected to an input pin included in the second input pin group. The first logic circuit LC1 and the fourth logic circuit LC4 among the first to fourth logic circuits LC1 to LC4 may be respectively connected exclusively to input pins included in the third input pin group. In some example embodiments, the first to fourth logic circuits LC1 to LC4 may correspond to an identical logic. For example, the first to fourth logic circuits LC1 to LC4 may correspond to an AOI logic, an AO logic, an OAI logic, or an OA logic.

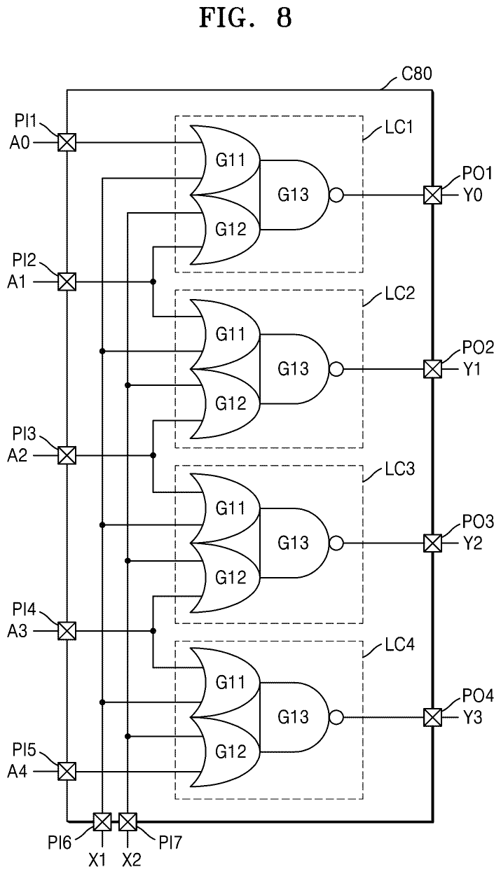

FIG. 8 is a diagram showing a cell C80 according to some example embodiments. For example, FIG. 8 shows an example of the cell C70 of FIG. 7. As described above with reference to FIG. 7, the cell C80 of FIG. 8 may include a plurality of logic circuits, and may include a first input pin group including at least one input pin commonly connected to the plurality of logic circuits, a second input pin group including at least one input pin connected to two or more logic circuits among the plurality of logic circuits, and/or a third input pin group including at least one input pin respectively connected exclusively to at least one of the plurality of logic circuits.

Referring to FIG. 8, the cell C80 may include the first to fourth logic circuits LC1 to LC4, and each of the first to fourth logic circuits LC1 to LC4 may correspond to an OAI22 logic. The first to fourth logic circuits LC1 to LC4 may commonly receive input bit signals X1 and X2, and to this end, may be commonly connected to the sixth input pin PI6 and/or the seventh input pin PI7. The first logic circuit LC1 and the second logic circuit LC2 may commonly receive the input bit signal A1, and to this end, may be commonly connected to the second input pin PI2. The second logic circuit LC2 and the third logic circuit LC3 may commonly receive the input bit signal A2, and to this end, may be commonly connected to the third input pin PI3. The third logic circuit LC3 and the fourth logic circuit LC4 may commonly receive the input bit signal A3, and to this end, may be commonly connected to the fourth input pin PI4. The first logic circuit LC1 and the fourth logic circuit LC4 may respectively receive exclusively the input bit signals A0 and/or A4, and to this end, may be respectively connected exclusively to the first input pin PI1 and/or the fifth input pin PI5. Accordingly, the sixth and/or seventh input pins PI6 and/or PI7 may be included in the first input pin group, the second to fourth input pins PI2 to PI4 may be included in the second input pin group, and the first input pin PI1 and/or the fifth input pin PI5 may be included in the third input pin group. The first to fourth logic circuits LC1 to LC4 may respectively output the output bit signals Y0 to Y3 via the first to fourth output pins PO1 to PO4.

In some example embodiments, the cell C80 may be included in a multiplier. For example, the input bit signals A0 to A4 may correspond to at least a portion of a first operand, the input bit signals X1 and/or X2 may correspond to at least a portion of a booth encoded second operand, and the output bit signals Y0 to Y3 may correspond to a partial product. When the first to fourth logic circuits LC1 to LC4 are provided as four independent OAI22 cells, 20 routings may be required, or sufficient, for input pins and output pins. The cell C80 of FIG. 8 may require 11 routings for the first to seventh input pins PI1 to PI7 and the first to fourth output pins PO1 to PO4, and accordingly, available routing resources may increase.

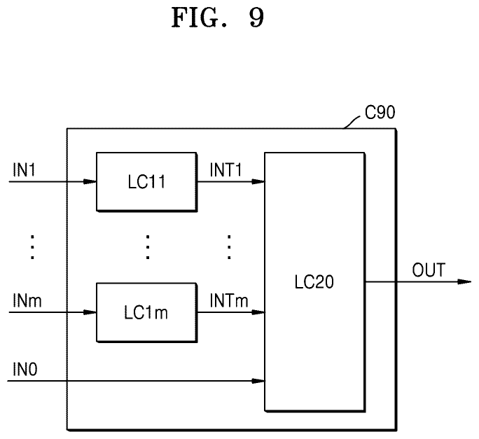

FIG. 9 is a block diagram showing a cell C90 according to some example embodiments. Referring to FIG. 9, the cell C90 may receive first to m^{th} input signals IN1 to INm and an input signal IN0, and may generate the output signal OUT (wherein m is an integer greater than 0). Each, or one or more, of the first to m^{th} input signals IN1 to INm, the input signal IN0, and/or the output signal OUT may be a single-bit signal or a multi-bit signal.

In some example embodiments, a complex cell may include cascaded logic circuits. For example, as shown in FIG. 9, the cell C90 may include first to m^{th} logic circuits LC1 to LCm and/or a logic circuit LC20. The first to m^{th} logic circuits LC1 to LCm may respectively generate first to m^{th} internal bit signals INT1 to INTm from the first to m^{th} input signals IN1 to INm. The logic circuit LC20 may generate the output signal OUT from the first to m^{th} internal bit signals INT1 to INTm and the input signal IN0. In some example embodiments, the first to m^{th} logic circuits LC1 to LCm may correspond to an identical logic. For example, the first to m^{th} logic circuits LC1 to LCm may correspond to an AOI logic, an AO logic, an OAI logic, and/or an OA logic. In some example embodiments, the logic circuit LC20 may correspond to a multi-input single-output logic. For example, the logic circuit LC20 may correspond to a NAND gate, an AND gate, a NOR gate, and/or an OR gate.

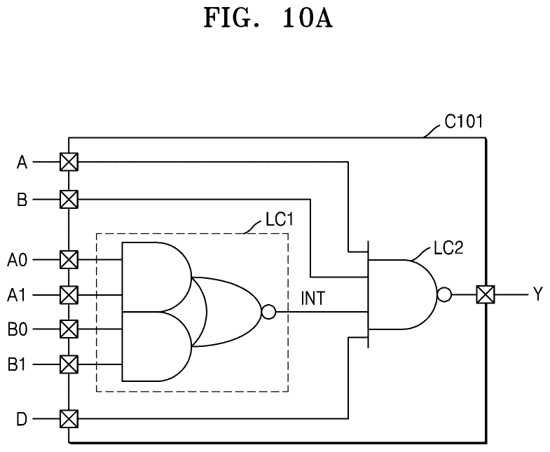

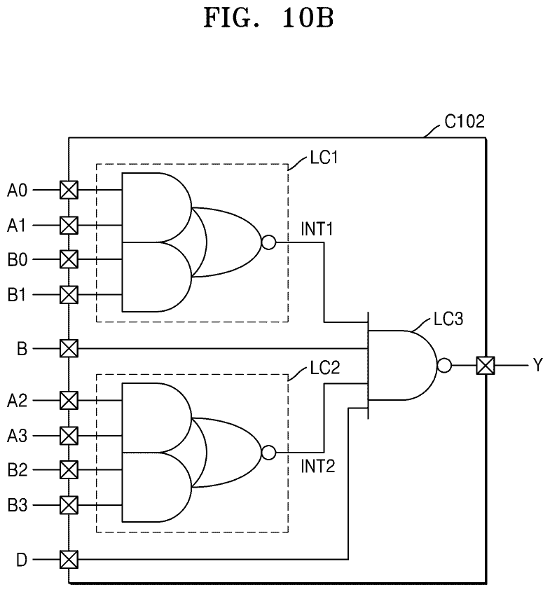

FIGS. 10A and 10B are diagrams showing examples of a cell according to some example embodiments. For example, FIGS. 10A and 10B show examples of the cell C90 of FIG. 9. As described above with reference to FIG. 9, each, or one or more, of cells C101 and/or C102 of FIGS. 10A and 10B may include a plurality of cascaded logic circuits.

Referring to FIG. 10A, the cell C101 may include the first logic circuit LC1 and/or the second logic circuit LC2. The first logic circuit LC1 may correspond to an AOI22 logic, and the second logic circuit LC2 may correspond to a 4-input NAND gate. The first logic circuit LC1 may generate an internal bit signal INT from the input bit signals A0, A1, B0, and/or B1. The second logic circuit LC2 may generate the output bit signal Y from input bit signals A, B, and/or D and/or the internal bit signal INT.

Referring to FIG. 10B, the cell C102 may include the first logic circuit LC1, the second logic circuit LC2, and/or the third logic circuit LC3. Each, or one or more, of the first logic circuit LC1 and/or the second logic circuit LC2 may correspond to an AOI22 logic, and the third logic circuit LC3 may correspond to a 4-input NAND gate. The first logic circuit LC1 may generate the first internal bit signal INT1 from the input bit signals A0, A1, B0, and/or B1. The second logic circuit LC2 may generate the second internal bit signal INT2 from the input bit signals A2, A3, B2, and/or B3. The third logic circuit LC3 may generate the output bit signal Y from input bit signals B and D, the first internal bit signal INT1, and/or the second internal bit signal INT2.

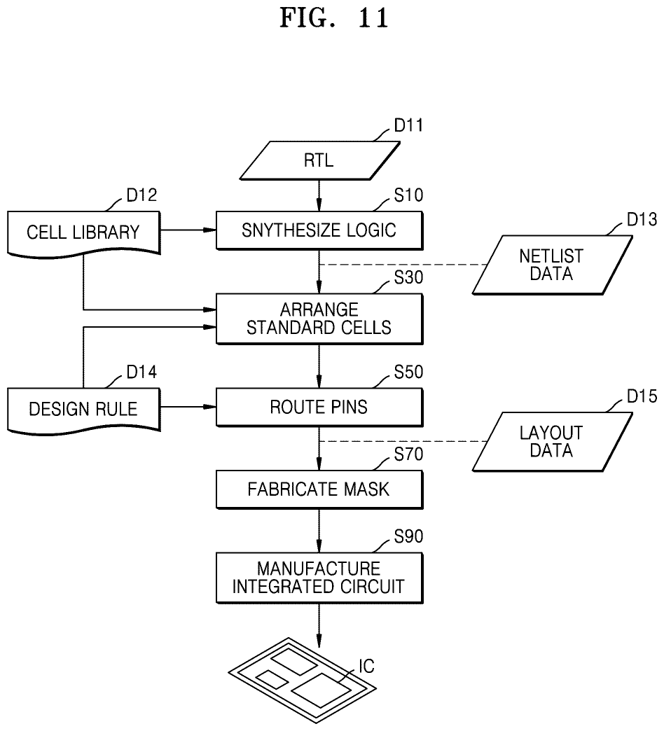

FIG. 11 is a flowchart showing a method of manufacturing an integrated circuit IC, according to some example embodiments. In detail, the flowchart of FIG. 11 shows an example of a method of manufacturing the integrated circuit IC including standard cells. A standard cell is a unit of a layout included in an integrated circuit, and may be designed to perform a predefined function. As shown in FIG. 11, the method of manufacturing the integrated circuit IC may include operations S10, S30, S50, S70, and/or S90.

A cell library (or standard cell library) D12 may include information about standard cells, for example, information about functions, characteristics, layouts, and/or the like. In some example embodiments, the cell library D12 may define not only a cell corresponding to one logic circuit but also a cell including a plurality of logic circuits, that is, a complex cell.

A design rule D14 may include requirements that a layout of the integrated circuit IC must comply with. For example, the design rule D14 may include requirements for a space between patterns in the same layer, a minimum width of a pattern, a routing direction of a wiring layer, and/or the like. In some example embodiments, the design rule D14 may define a minimum separation distance within the same track of a wiring layer.

In operation S10, a logic synthesis operation of generating netlist data D13 from RTL data D11 may be performed. For example, a semiconductor design tool (for example, a logic synthesis tool) may perform logic synthesis by referring to the cell library D12 from the RTL data D11 written in a hardware description language (HDL), such as VHSIC hardware description language (VHDL) and Verilog, and may generate the netlist data D13 including a bitstream and/or a netlist. The netlist data D13 may correspond to an input of place and routing to be described below.

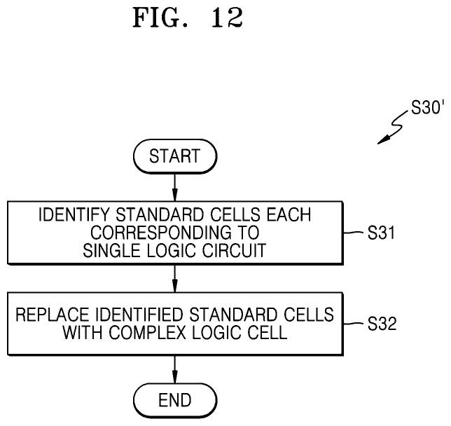

In operation S30, standard cells may be arranged. For example, a semiconductor design tool (for example, a P&R tool) may arrange standard cells used in the netlist data D13 by referring to the cell library D12. In some example embodiments, the semiconductor design tool may arrange a standard cell in a row extending in an X-axis direction, and the standard cell may receive power from a power rail extending along boundaries of the row. An example of operation S30 is described below with reference to FIG. 12.

In operation S50, pins of standard cells may be routed. For example, a semiconductor design tool may generate interconnections electrically connecting output pins of arranged standard cells to input pins thereof, and may generate layout data D15 that defines the arranged standard cells and/or the generated interconnections. The layout data D15 may have a format, such as GDSII, and may include geometric information of cells and interconnections. The semiconductor design tool may refer to the design rule D14 while routing the pins of the cells. The layout data D15 may correspond to an output of place and/or routing. Operation S50 may alone be or operation S30 and operation S50 may collectively be referred to as a method of designing an integrated circuit.

In operation S70, an operation of fabricating a mask may be performed. For example, optical proximity correction (OPC) for correcting a distortion phenomenon, such as refraction, caused by characteristics of light in photolithography may be applied to the layout data D15. Patterns on a mask may be defined to form patterns arranged in a plurality of layers based on OPC-applied data, and at least one mask (or photomask) for forming patterns of each of a plurality of layers may be fabricated. In some example embodiments, the layout of the integrated circuit IC may be restrictively modified in operation S70, and the restrictive modification of the integrated circuit IC in operation S70 may be referred to as design polishing as post-processing for optimizing the structure of the integrated circuit IC.

In operation S90, an operation of manufacturing the integrated circuit IC may be performed. For example, the integrated circuit IC may be manufactured by patterning a plurality of layers by using at least one mask fabricated in operation S70. Front-end-of-line (FEOL) may include, for example, planarizing and cleaning a wafer, forming a trench, forming a well, forming a gate electrode, and/or forming a source and/or a drain. Individual elements, such as transistors, capacitors, resistors, and/or the like, may be formed on a substrate by FEOL. In addition, back-end-of-line (BEOL) may include, for example, silicidating a gate and/or source and/or drain regions, adding a dielectric, planarizing, forming a hole, adding a metal layer, forming a via, forming a passivation layer, and/or the like. Individual elements, such as transistors, capacitors, resistors, and/or the like, may be interconnected by BEOL. In some example embodiments, middle-of-line (MOL) may be performed between FEOL and BEOL, and contacts may be formed on individual elements. Afterwards, the integrated circuit IC may be packaged in a semiconductor package and may be used as a component in various applications.

FIG. 12 is a flowchart showing a method of designing an integrated circuit, according to some example embodiments. For example, the flowchart of FIG. 12 shows an example of operation S30 of FIG. 11. As described above with reference to FIG. 11, standard cells may be arranged in operation S30′ of FIG. 12. As shown in FIG. 12, operation S30′ may include operation S31 and/or operation S32. Hereinafter, FIG. 12 is described with reference to FIG. 11.

Referring to FIG. 12, standard cells each corresponding to a single logic circuit may be identified in operation S31. For example, a semiconductor design tool may identify a plurality of standard cells each corresponding to a single logic circuit and connected to each other in the netlist data D13. In some example embodiments, the semiconductor design tool may identify standard cells that share at least one input bit signal. In some example embodiments, the semiconductor design tool may identify standard cells respectively corresponding to cascaded logic circuits. In some example embodiments, the semiconductor design tool may identify standard cells corresponding to an identical logic.

In operation S32, the identified standard cells may be replaced with a complex logic cell. For example, a semiconductor design tool may identify, from the cell library D12, a complex logic cell corresponding to the standard cells identified in operation S31. The semiconductor design tool may replace the standard cells identified in operation S31 with the complex logic cell. Due to the complex logic cell, nodes (or nets) for connection between the identified standard cells may be reduced, or removed, and routing may be omitted in subsequent operation S50.

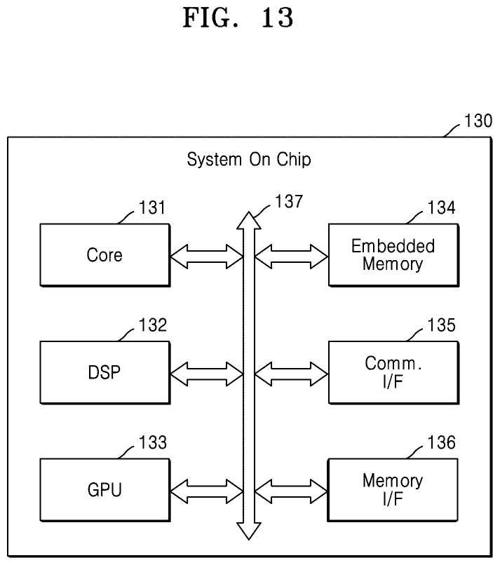

FIG. 13 is a block diagram showing a system-on-chip (SoC) 130 according to some example embodiments. The SoC 130 may be referred to as an integrated circuit in which components of a computing system and/or another electronic system are integrated. For example, an application processor (AP) as an example of the SoC 130 may include a processor and/or components for other functions. The SoC 130 may include a complex cell described above with reference to the drawings, and accordingly, may have a higher degree of integration, a smaller area, and/or improved performance. As shown in FIG. 13, the SoC 130 may include a core 131, a digital signal processor (DSP) 132, a graphics processing unit (GPU) 133, an embedded memory 134, a communication interface 135, and/or a memory interface 136. Components of the SoC 130 may communicate with each other via a bus 137.

The core 131 may process instructions and control the operation of the components included in the SoC 130. For example, the core 131 may drive an operating system and execute applications on the operating system by processing a series of instructions. The DSP 132 may generate useful data by processing a digital signal, for example, a digital signal provided from the communication interface 135. The GPU 133 may generate, from image data provided from the embedded memory 134 and/or the memory interface 136, data for an image output via a display device, and may encode the image data. The embedded memory 134 may store data required, or sufficient, for the core 131, the DSP 132, and/or the GPU 133 to operate. The communication interface 135 may provide an interface for a communication network or one-to-one communication. The memory interface 136 may provide an interface with respect to an external memory of the SoC 130, for example, dynamic random access memory (DRAM), flash memory, or the like.

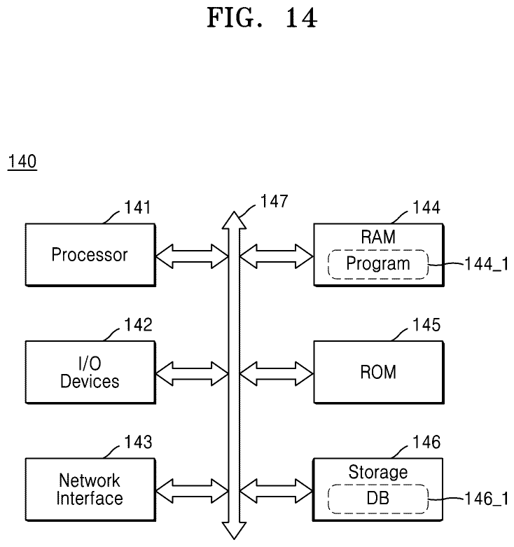

FIG. 14 is a block diagram showing a computing system 140 including a memory storing a program, according to some example embodiments. According to some example embodiments, a method of designing an integrated circuit, for example, at least some of operations in the flowchart described above, may be performed by the computing system (or computer) 140.

The computing system 140 may be a stationary computing system, such as a desktop computer, a workstation, and/or a server, and/or may be a portable computing system, such as a laptop computer. As shown in FIG. 14, the computing system 140 may include a processor 141, input/output devices 142, a network interface 143, random access memory (RAM) 144, read only memory (ROM) 145, and/or a storage 146. The processor 141, the input/output devices 142, the network interface 143, the RAM 144, the ROM 145, and/or the storage 146 may be connected to a bus 147, and may communicate with each other via the bus 147.

The processor 141 may be referred to as a processing unit, and for example, like a microprocessor, an AP, a DSP, and/or a GPU, the processor 141, may include at least one core capable of executing any instruction set (for example, Intel Architecture-32 (IA-32), 64-bit extension IA-32, x86-64, PowerPC, Sparc, MIPS, ARM, or IA-64). For example, the processor 141 may access a memory, that is, the RAM 144 and/or the ROM 145, via the bus 147, and may execute instructions stored in the RAM 144 and/or the ROM 145.

The RAM 144 may store a program 144_1 for a method of designing an integrated circuit according to some example embodiments or at least a portion thereof, and the program 144_1 may allow the processor 141 to perform a method of designing an integrated circuit, for example, at least some of operations of FIG. 11. In other words, the program 144_1 may include a plurality of instructions executable by the processor 141, and the plurality of instructions included in the program 144_1 may allow the processor 141 to perform, for example, at least some of operations included in the flowcharts described above.

The storage 146 may not lose stored data even when power supplied to the computing system 140 is cut off. For example, the storage 146 may include a non-volatile memory device, and/or may include a storage medium, such as magnetic tape, an optical disk, and/or a magnetic disk. In addition, the storage 146 may be detachable from the computing system 140. The storage 146 may store the program 144_1 according to some example embodiments, and before the program 144_1 is executed by the processor 141, the program 144_1 or at least a portion thereof may be loaded into the RAM 144 from the storage 146. Alternatively, the storage 146 may store a file written in a program language, and the program 144_1 generated by a compiler or the like from the file or at least a portion thereof may be loaded into the RAM 144. In addition, as shown in FIG. 14, the storage 146 may store a database 146_1, and the database 146_1 may include information necessary, or sufficient, for designing an integrated circuit, for example, information about designed blocks, the cell library D12 and/or the design rule D14 of FIG. 11.

The storage 146 may also store data to be processed by the processor 141 and/or data processed by the processor 141. In other words, the processor 141 may generate data by processing data stored in the storage 146 according to the program 144_1 and may store the generated data in the storage 146. For example, the storage 146 may store the RTL data D11, the netlist data D13, and/or the layout data D15 of FIG. 11.

The input/output devices 142 may include input devices, such as keyboards and/or pointing devices, and may include output devices, such as display devices and/or printers. For example, a user may trigger execution of the program 144_1 by the processor 141 via the input/output devices 142, may input the RTL data D11 and/or the netlist data D13 of FIG. 11, and/or may check the layout data D15 of FIG. 11.

The network interface 143 may provide access to a network outside the computing system 140. For example, a network may include a plurality of computing systems and/or communication links, and the communication links may include wired links, optical links, wireless links, and/or any other type of links.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. An integrated circuit comprising a plurality of cells in a series of rows, wherein
a first cell of the plurality of cells includes
a plurality of logic circuits, each logic circuit of the plurality of logic circuits configured to independently generate an output bit signal according to input bit signals,
a first input pin group including at least one input pin commonly connected to the plurality of logic circuits,
a second input pin group including at least one input pin commonly connected to two or more logic circuits among the plurality of logic circuits, and
a third input pin group including at least one input pin respectively connected exclusively to at least one of the plurality of logic circuits.

2. The integrated circuit of claim 1, wherein the plurality of logic circuits correspond to an identical logic.

3. The integrated circuit of claim 2, wherein each logic circuit of the plurality of logic circuits corresponds to an OAI22 logic including a first OR gate having a first input and a second input, a second OR gate having a third input and a fourth input, and a NAND gate.

4. The integrated circuit of claim 3, wherein
the plurality of logic circuits includes first to fourth logic circuits respectively connected to first to fourth output pins, and
the first input pin group includes
a first input pin connected to a first input of each of the first to fourth logic circuits, and
a second input pin connected to a third input of each of the first to fourth logic circuits.

5. The integrated circuit of claim 4, wherein
the third input pin group includes
a third input pin connected to a second input of the first logic circuit, and
a seventh input pin connected to a fourth input of the fourth logic circuit, and
the second input pin group includes
a fourth input pin connected to a fourth input of the first logic circuit and a second input of the second logic circuit,
a fifth input pin connected to a fourth input of the second logic circuit and a second input of the third logic circuit, and
a sixth input pin connected to a fourth input of the third logic circuit and a second input of the fourth logic circuit.

6. The integrated circuit of claim 1, wherein the first cell is configured to:
receive a booth encoded first operand via the first input pin group;
receive a second operand via the second input pin group and the third input pin group; and
output a partial product.

7. The integrated circuit of claim 1, wherein the first cell is in one row or two or more rows adjacent to each other, among the series of rows.

8. An integrated circuit comprising a plurality of cells in a series of rows, wherein
a first cell of the plurality of cells includes
a plurality of logic circuits, each logic circuit of the plurality of logic circuits corresponding to an identical logic and configured to independently generate an output bit signal according to input bit signals,
a first input pin group including at least one input pin commonly connected to the plurality of logic circuits, and
a second input pin group including a plurality of input pins respectively connected exclusively to the plurality of logic circuits.

9. The integrated circuit of claim 8, wherein
the first input pin group includes a first input pin and a second input pin, and
each logic circuit of the plurality of logic circuits corresponds to a logic including
a first logic gate connected to the first input pin and an input pin included in the second input pin group, and
a second logic gate connected to the second input pin, the second logic gate configured to receive an output bit signal of the first logic gate.

10. The integrated circuit of claim 9, wherein each of the plurality of logic circuits corresponds to an AOI21 logic in which the first logic gate is an AND gate and the second logic gate is a NOR gate.

11. The integrated circuit of claim 9, wherein each of the plurality of logic circuits corresponds to an OAI21 logic in which the first logic gate is an OR gate and the second logic gate is a NAND gate.

12. The integrated circuit of claim 8, wherein
the first input pin group includes a first input pin and a second input pin, and
each of the plurality of logic circuits corresponds to a logic including
a first logic gate connected to the first input pin and one of a plurality of input pins included in the second input pin group,
a second logic gate connected to the second input pin and another one of the plurality of input pins included in the second input pin group, and
a third logic gate configured to receive an output bit signal of the first logic gate and an output bit signal of the second logic gate.

13. The integrated circuit of claim 12, wherein each of the plurality of logic circuits corresponds to an OAI22 logic in which each of the first logic gate and the second logic gate is an OR gate and the third logic gate is a NAND gate.

14. The integrated circuit of claim 12, wherein each of the plurality of logic circuits corresponds to an AOI22 logic in which each of the first logic gate and the second logic gate is an AND gate and the third logic gate is a NOR gate.

15. The integrated circuit of claim 8, wherein the first cell is in one row or two or more rows adjacent to each other, among the series of rows.

16. An integrated circuit comprising a plurality of cells in a series of rows, wherein
a first cell of the plurality of cells includes
a first input pin group,
a second input pin group,
a first logic circuit configured to generate an internal bit signal based on first input bit signals received via the first input pin group, and
a second logic circuit configured to generate an output bit signal based on the internal bit signal received from the first logic circuit and on second input bit signals received via the second input pin group, and
the first logic circuit corresponds to a logic comprising two or more cascaded logic gates.

17. The integrated circuit of claim 16, wherein
the first cell further includes
a third input pin group, and
a third logic circuit configured to generate an internal bit signal, based on third input bit signals received via the third input pin group, and
the third logic circuit corresponds to the logic of the first logic circuit.

18. The integrated circuit of claim 16, wherein
the first logic circuit corresponds to an AOI22 logic comprising two AND gates and a NOR gate, and
the second logic circuit corresponds to a NAND gate.

19. The integrated circuit of claim 16, wherein
the first logic circuit corresponds to an OAI22 logic comprising two OR gates and a NAND gate, and
the second logic circuit corresponds to a NOR gate.

20. The integrated circuit of claim 16, wherein the first cell is in one row or two or more rows adjacent to each other, among the series of rows.
